(19) United States
(12) Patent Application Publication
(10) Pub. No.: US 2013/0025667 A1
(43) Pub. Date: Jan. 31, 2013

(54) Electrode Structure for Improving Efficiency of Solar Cells

(71) Applicants: Sheng-Fu Horng, Hsinchu (TW); Ming-Kun Lee, Hsinchu (TW); Jen-Chun Wang, Hsinchu (TW); Yun-Ru Horng, Hsinchu (TW); Hsin-Fei Meng, Hsinchu (TW)

(72) Inventors: Sheng-Fu Horng, Hsinchu (TW); Ming-Kun Lee, Hsinchu (TW); Jen-Chun Wang, Hsinchu (TW); Yun-Ru Horng, Hsinchu (TW); Hsin-Fei Meng, Hsinchu (TW)

(73) Assignee: NATIONAL TSING HUA UNIVERSITY, Hsinchu (TW)

(21) Appl. No.: 13/542,991

(22) Filed: Jul. 6, 2012

(30) Foreign Application Priority Data
Jul. 27, 2011 (TW) 100126559

(51) Int. Cl. H01L 31/0224

(52) U.S. Cl. 136/256

(57) ABSTRACT

The present invention provides an improved electrode structure for improving efficiency of solar cells, and the structure of the solar cells includes a back electrode, a transparent conducting glass layer, a photoelectric conversion layer, and a grid electrode. The transparent conducting glass layer includes a light-penetrated surface for accepting light. The photoelectric conversion layer is disposed between the back electrode and the transparent conducting glass layer to convert light energy into electric energy. The grid electrode is embedded in the transparent conducting glass layer to solve the problems of uneven electric potential for decreasing uneven voltage on the light-penetrated surface and further increasing efficiency of the solar cells.

### CROSS-REFERENCE TO RELATED APPLICATIONS

This Non-provisional application claims priority under 35 U.S.C. §119(a) on Patent Application No(s). 100126559 filed in Taiwan, Republic of China, Jul. 27, 2011, the entire contents of which are hereby incorporated by reference.

### FIELD OF THE INVENTION

This invention relates to an improved structure of solar cells for improving efficiency of solar cells.

### BACKGROUND OF THE INVENTION

Due to greenhouse effect causing from excessive use of fossil fuels as well as the economic factors causing from continuously rising prices of crude oil, at present, to find alternative energy sources has become an imperative issue. The alternative energy sources such as wind, hydro, geothermal, bio-diesel and solar cells, are very interesting alternatives of green energy. Among all the alternatives, the solar cells develop broadly because of its high efficiency and mature technology.

There are several materials for producing solar cells, including single-crystal silicon, polycrystalline silicon, amorphous silicon, gallium arsenide, antimony, cadmium, copper, indium and selenium. In recent years, a serious lack of poly-silicon causes more attention on thin film solar cells that only need very little materials. Among all the thin film solar cells, amorphous silicon solar cells is the most popular one because it has no concerns with environmental pollution.

The joint methods of P-N junctions between crystalline silicon solar cell and amorphous silicon solar cell are different. The photoelectric conversion effect (PCE) of amorphous silicon solar cells will be limited due to many flaws between the P-N junctions if the P-N junction layers directly joint with each other. It is necessary to use two thin P-N layers sandwiching a non-doped I-layer to obtain better photoelectric conversion effects.

### SUMMARY OF THE INVENTION

A structure of the solar cells includes a side as light-penetrated side for accepting light, and the other side is light-barricaded side (thick metal as electrode with high conducting efficiency). The light-penetrated side includes high light-penetrated efficiency, so as to cause lower conducting efficiency. The lower conducting efficiency will lead to the light-penetrated side with uneven electric potential, when the solar cell with big area is operated. The uneven electric potential will lead to decrease the efficiency of the solar cells. The big area of the solar cells can be taken as the combination of a plurality of small areas of the solar cells. The uneven electric potential will make all small areas of the solar cells not be operated at the best efficiency.

As a result, the present invention provides an improved electrode structure for improving efficiency of solar cells. The grid electrode is embedded in the transparent conducting glass layer to solve the problems of uneven electric potential mentioned above. However, the embedded position will barricade some light, how to design the way of embedding the grid electrode, and how to solve the problem of the uneven electric potential and light-barricaded situation is the main purpose of the invention.

The present invention provides an improved electrode structure for improving efficiency of solar cells, and the structure of the solar cells includes a back electrode, a transparent conducting glass layer, a photoelectric conversion layer and a grid electrode. The transparent conducting glass layer includes a light-penetrated surface for accepting light. The photoelectric conversion layer is disposed between the back electrode and the transparent conducting glass layer to convert light energy into electric energy. The grid electrode is embedded in the transparent conducting glass layer to solve the problems of uneven electric potential for decreasing uneven voltage on the light-penetrated surface and further increasing efficiency of the solar cells.

In an embodiment, the grid electrode includes a V-type shape with a default angle, such as an acute angle, an obtuse angle or a right angle. In another embodiment, the grid electrode includes a straight-line shape.

The present invention provides different electrode design and the way of embedding the grid electrode in the transparent conducting glass layer to solve the problems of uneven electric potential for decreasing uneven voltage on the light-penetrated surface and further increasing efficiency of the solar cells.

### BRIEF DESCRIPTION OF THE DRAWINGS

FIG. 1 shows a cross-section view of the solar cells.

FIG. 2A-2D show vertical views of the grid electrodes with different angles based on fixed area.

FIG. 3 shows efficiency of the grid electrodes with different angles.

Table 1 shows all data detected from the grid electrode with different angles of the solar cells.

Table 2 shows the data of the PCE of the grid electrode with different angles based on a situation.

### DETAILED DESCRIPTION OF THE INVENTION

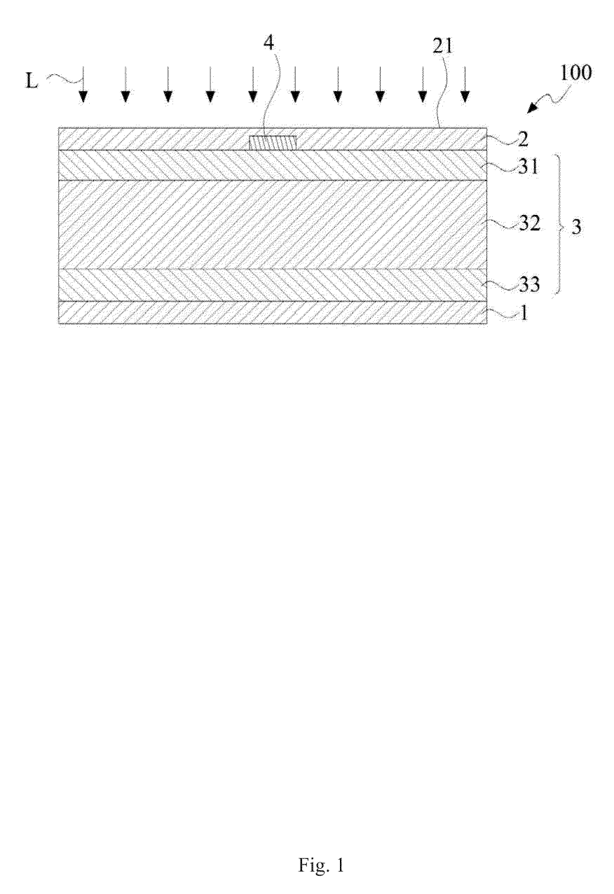

Please refer to the FIG. 1 showing a cross-section view of the solar cells. As shown in FIG. 1, in the embodiment, the structure of the solar cells 100 includes a back electrode 1, a transparent conducting glass layer 2, a photoelectric conversion layer 3 and a grid electrode 4. The transparent conducting glass layer 2 includes a light-penetrated surface 21 for accepting light.

The photoelectric conversion layer 3 is disposed between the back electrode 1 and the transparent conducting glass layer 2. The photoelectric conversion layer 3 is composed of a P-type layer 31, an I-type layer 32 and a N-type layer 33. The photoelectric conversion layer 3 is used to absorb light L passed through the light-penetrated surface 21 and convert light energy into electric energy.

The present invention is characterized in that the grid electrode 4 made of metal or electrically conductive polymer is embedded in the transparent conducting glass layer 2 to solve the problems of uneven electric potential for decreasing uneven voltage on the light-penetrated surface 21 and further increasing efficiency of the solar cells 100. By using numerical analysis method to get the 2D distribution of voltage in electrode and by different electrode design, the problems of uneven voltage and efficiency of the cells can be resolved, and further to solve the problems of uneven electric potential. In the embodiment, the amorphous silicon (a-Si) thin-film solar cell is taken as an example of the solar cells 100, but not limited thereof, it can be any kind of solar cells.

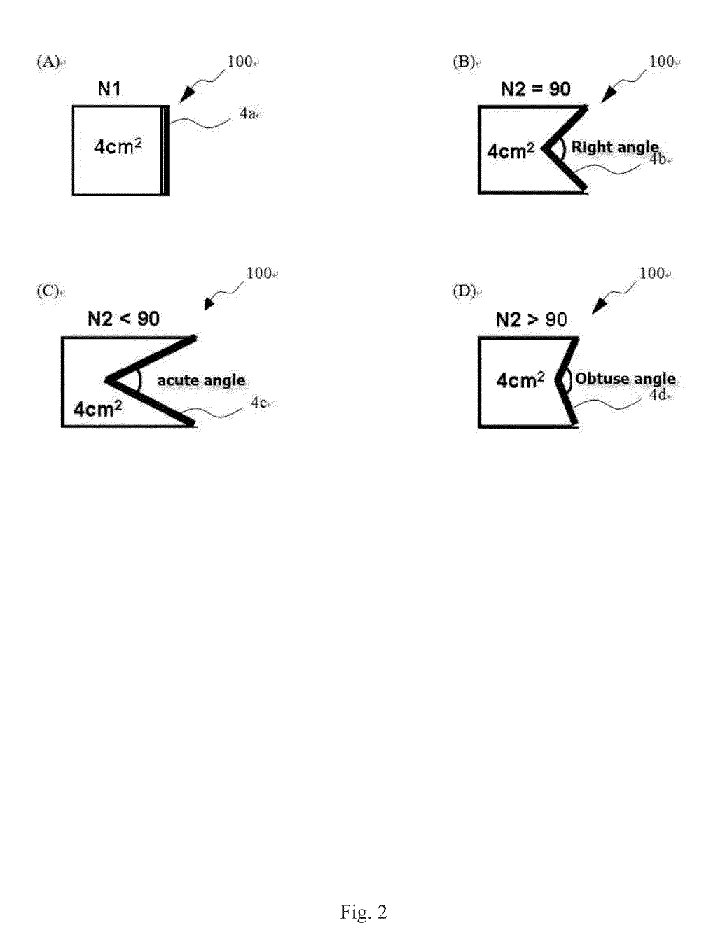

Please refer to FIG. 2A-2D respectively showing vertical views of the grid electrodes with different angles based on fixed area. The grid electrode includes a V-type shape with a default angle, such as the grid electrode 4a with straight-line shape shown in FIG. 2A, the grid electrode 4b with a right angle shown in FIG. 2B, the grid electrode 4c with an acute angle shown in FIG. 2C, and the grid electrode 4d with an obtuse angle shown in FIG. 2D.

Please refer to table 1 showing all data detected from the grid electrode with different angles of the solar cells. It can be known from the table 1 that different efficiency is generated by different shapes of grid electrode. In the embodiment, the perfected efficiency (2.90%) is generated by the acute angle) (angle<90°) of the grid electrode.

TABLE 1

| | angle = 180° | angle = 90° | angle <90° | angle >90° |
|---|---|---|---|---|
| Current density | −7.24 | −7.25 | 7.26 | 7.24 |
| (mA/cm²) | | | | |
| Voltage (V) | 0.63 | 0.63 | 0.63 | 0.63 |
| Factor | 56.6 | 59.2 | 63.8 | 57.3 |
| Efficiency (%) | 2.57 | 2.69 | 2.90 | 2.60 |
| Average | 0.50 | 0.48 | 0.45 | 0.49 |
| (Maximum | | | | |
| efficiency point) | | | | |
| Standard deviation | 0.036 | 0.033 | 0.023 | 0.037 |
| (Maximum | | | | |
| efficiency point) | | | | |

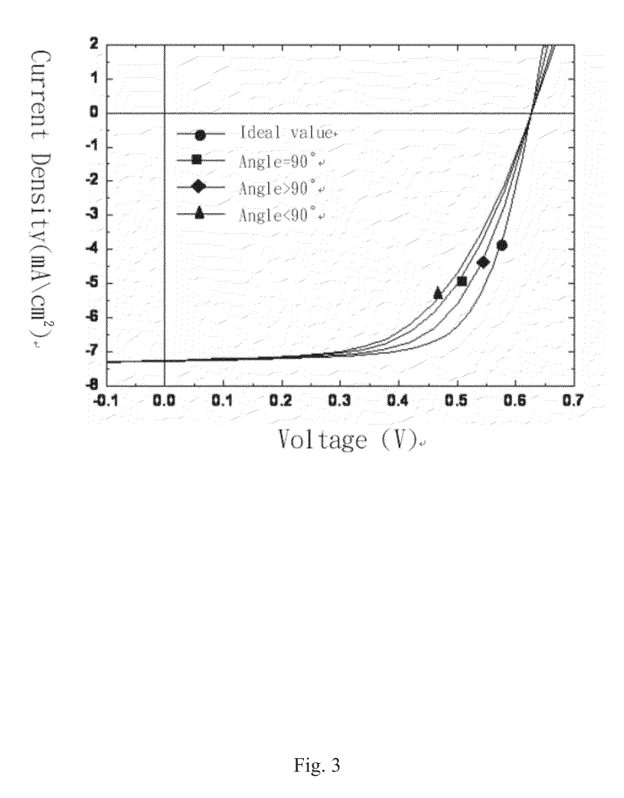

Please refer to FIG. 3 showing efficiency of the grid electrodes with different angles. It can be known from the FIG. 3 that the four curves respectively shows the efficiency of the grid electrodes with different angles, such as the ideal value, the right angle, the acute angle and the obtuse angle. In the embodiment, the perfected efficiency is generated by the acute angle of the grid electrode.

Please refer to table 2 showing the data of the photoelectric conversion effect (PCE) of the grid electrode with different angles based on a situation. The situation comprises keeping fixed cross-section area of the grid electrode, keeping fixed area of the grid electrode for generating photoelectrons, and correcting factors for PCE with considering light barricade or without considering light barricade. In theory, in the situation without considering light barricade, when the grid electrode includes the smaller angle, the conversion efficiency is higher. However, the real situation is not corresponding to the theory. It can be known from the table 2 that in the situation with considering light barricade, the angle of the grid electrode is not inverse proportion to the conversion efficiency.

The highest conversion efficiency needs to correspond to a certain angle of the grid electrode. For example, in the embodiment, when the angle of the grid electrode is 54°, the highest conversion efficiency is generated. When in the situation without considering light barricade, the PCE=2.9%, and when in the situation with considering light barricade, the PCE=2.61%, and it's the perfected efficiency.

TABLE 2

| | | N2 | N2 | N2 | N2 |
|---|---|---|---|---|---|
| | N1 | (127°) | (90°) | (54°) | (28°) |
| PCE (%) | 2.57 | 2.60 | 2.69 | 2.90 | 3.05 |
| (without considering light | | | | | |
| barricade) | | | | | |
| PCE (%) | 2.45 | 2.46 | 2.51 | 2.61 | 2.53 |
| (considering light barricade) | | | | | |

Although the present invention has been described in terms of specific exemplary embodiments and examples, it will be appreciated that the embodiments disclosed herein are for illustrative purposes only and various modifications and alterations might be made by those skilled in the art without departing from the spirit and scope of the invention as set forth in the following claims.

What is claimed is:

1. An improved electrode structure for improving efficiency of solar cells, comprising:
a back electrode;
a transparent conducting glass layer having a light-penetrated surface; and
a photoelectric conversion layer disposed between the back electrode and the transparent conducting glass layer to absorb light passing through the light-penetrated surface and convert light energy into electric energy;
characterized in that the transparent conducting glass layer embeds at least a grid electrode made of metal or electrically conductive polymer to decrease uneven voltage on the light-penetrated surface and to increase efficiency of the solar cells.

2. The improved electrode structure for improving efficiency of solar cells according to claim 1, wherein the grid electrode made of metal or electrically conductive polymer comprises a V-type shape with a default angle.

3. The improved electrode structure for improving efficiency of solar cells according to claim 2, wherein the default angle of the grid electrode made of metal or electrically conductive polymer is an acute angle.

4. The improved electrode structure for improving efficiency of solar cells according to claim 2, wherein the default angle of the grid electrode made of metal or electrically conductive polymer is an obtuse angle.

5. The improved electrode structure for improving efficiency of solar cells according to claim 2, wherein the default angle of the grid electrode made of metal or electrically conductive polymer is a right angle.

6. The improved electrode structure for improving efficiency of solar cells according to claim 2, wherein the grid electrode made of metal or electrically conductive polymer comprises a straight-line shape.
